(19) United States
(12) Patent Application Publication
(10) Pub. No.: US 2025/0273474 A1
(43) Pub. Date: Aug. 28, 2025

(54) METHOD AND SYSTEM FOR PROCESSING SUBSTRATE

(71) Applicant: SEMES CO., LTD., Cheonan-si (KR)

(72) Inventors: Seong Gil LEE, Hwaseong-si (KR); Jong Wan KWON, Seongnam-si (KR); Seung Jun OH, Hwaseong-si (KR); Myoung Sub NOH, Hwaseong-si (KR); Dong Sub OH, Busan (KR)

(21) Appl. No.: 18/895,913

(22) Filed: Sep. 25, 2024

(30) Foreign Application Priority Data
Feb. 22, 2024 (KR) 10-2024-0025413

(51) Int. Cl. H01L 21/311; H01J 37/32

(52) U.S. Cl. CPC H01L 21/31116; H01J 37/3244; H01J 37/32733; H01J 37/32899

(57) ABSTRACT

The present disclosure provides a method and a system for processing a substrate. Provided is the method for processing a substrate including: introducing a substrate into a first chamber; performing first plasma processing on the substrate in the first chamber; removing the substrate from the first chamber; introducing the substrate into a second chamber; and performing second plasma processing on the substrate in the second chamber.

### CROSS-REFERENCE TO RELATED APPLICATION(S)

This application claims benefit of priority to Korean Patent Application No. 10-2024-0025413 filed on Feb. 22, 2024, in the Korean Intellectual Property Office, the disclosure of which is incorporated herein by reference in its entirety.

### BACKGROUND

### 1. Field

The present disclosure relates to a method and a system for processing a substrate.

### 2. Description of Related Art

Plasma refers to matter in a gaseous state separated into ions, radicals, electrons, or the like, at high temperatures. Plasma is generated by very high temperatures, strong electric fields, or high-frequency electromagnetic fields (RF electromagnetic fields).

A semiconductor device manufacturing process may include a process of etching a surface of a substrate to form a desired pattern on the substrate. The etching process may be performed by causing ions or radicals included in the plasma to collide with a thin film formed on the substrate or react with the thin film.

The roughness of the substrate surface generated in an etching process during a semiconductor device manufacturing process may be a factor deteriorating the performance of a finished product. Therefore, a technology to reduce the surface roughness of some areas of the substrate again after the etching process is required.

### SUMMARY

An aspect of the present disclosure is to provide a method and a system for processing a substrate which may reduce the roughness of a surface damaged in a process of etching a portion of a buried layer disposed in a channel hole formed in a substrate.

In an embodiment, the present disclosure is to provide a method and a system for processing a substrate which may move silicon particles by performing hydrogen plasma processing on an exposed surface of a polysilicon layer, and may reduce the roughness of the exposed surface of the polysilicon layer.

In order to achieve the above-mentioned purpose, the present disclosure provides a method and a system for processing a substrate as follows.

In an embodiment, provided is a method for processing a substrate, including: introducing a substrate into a first chamber; performing first plasma processing on the substrate in the first chamber; removing the substrate from the first chamber; introducing the substrate into a second chamber; and performing second plasma processing on the substrate in the second chamber, and the substrate includes one or more channel holes and a buried layer formed in the one or more channel holes, and different processing is performed on the substrate in the performing first plasma processing and the performing second plasma processing.

In an embodiment, provided is a system for processing a substrate, including: a first chamber including a first processing space and a first plasma generation unit generating plasma in the first processing space therein; a second chamber including a second processing space and a second plasma generating unit generating plasma in the second processing space; and a substrate transfer unit transferring a substrate between the first chamber and the second chamber, and the substrate includes one or more channel holes and a buried layer formed in the one or more channel holes, and different processing is performed on the substrate in the first chamber and the second chamber.

In an embodiment, provided is a method for processing a substrate, including: introducing a substrate into a first chamber; generating a first plasma from a first gas including fluorine in the first chamber; performing first plasma processing on the substrate in the first chamber; removing the substrate from the first chamber; introducing the substrate into a second chamber; generating a second plasma from a second gas including hydrogen in the second chamber; performing second plasma processing on the substrate in the second chamber, and the substrate includes one or more channel holes, a buried layer burying the one or more channel holes in the one or more channel holes, and a polysilicon layer disposed between the one or more channel holes and the buried layer and formed to cover an inner wall of the one or more channel holes, the performing first plasma processing includes etching an upper portion of the buried layer using the first plasma, and the performing second plasma processing includes processing an exposed surface of the polysilicon layer.

The present disclosure may provide a method and a system for processing a substrate which may reduce the roughness of a surface damaged in a process of etching a portion of a buried layer disposed in a channel hole formed in a substrate.

In an embodiment, the present disclosure may provide a method and a system for processing a substrate which may move silicon particles by performing hydrogen plasma processing on an exposed surface of a polysilicon layer, and may reduce the roughness of the exposed surface of the polysilicon layer.

### BRIEF DESCRIPTION OF DRAWINGS

The above and other aspects, features, and advantages of the present disclosure will be more clearly understood from the detailed following description, taken in conjunction with the accompanying drawings, in which:

FIG. 1 is a flow chart of a method for processing a substrate according to an embodiment of the present disclosure;

FIG. 2 is an exemplary illustration of a portion of a cross-section of a substrate on which a method for processing a substrate according to an embodiment of the present disclosure is performed;

FIG. 3 is a flow chart of a method for processing a substrate according to an embodiment of the present disclosure;

FIG. 4 is a schematic illustration of a portion of a system for processing a substrate according to an embodiment of the present disclosure;

FIG. 5 is an exemplary illustration of a portion of a cross-section of a substrate on which a method for processing a substrate according to an embodiment of the present disclosure is performed;

FIG. 6 is a flow chart of a method for processing a substrate according to an embodiment of the present disclosure;

FIG. 7 is a schematic illustration of a portion of a system for processing a substrate according to an embodiment of the present disclosure; and

FIG. 8 is an exemplary illustration of a portion of a cross-section of a substrate on which a method for processing a substrate according to an embodiment of the present disclosure is performed.

### DETAILED DESCRIPTION

Hereinafter, preferred example embodiments will be described in detail with reference to the accompanying drawings so that those of ordinary skill in the art may easily implement the present disclosure. However, in describing preferred example embodiments of the present disclosure in detail, when it is determined that a detailed description of related known functions or configurations may unnecessarily obscure the gist of the present disclosure, the detailed description thereof will be omitted. Furthermore, the same reference numbers are used throughout the drawings to refer to the same or similar functions and actions. In the present specification, it may be understood that the expressions such as “on,” “above,” “upper,” “below”, “beneath,” “lower,” and “side surface,” merely indicated based on drawings, and may actually vary depending on the direction in which the components are disposed.

Furthermore, throughout the specification, the terms “connected to” or “coupled to” are used to designate a connection or coupling of one element to another element and include both a case where an element is “directly connected or coupled to” another element and a case where an element is “indirectly connected or coupled to” another element via still another element. Furthermore, when a certain portion “includes” or “comprises” a certain component, this indicates that other components are not excluded and may be further included unless otherwise noted.

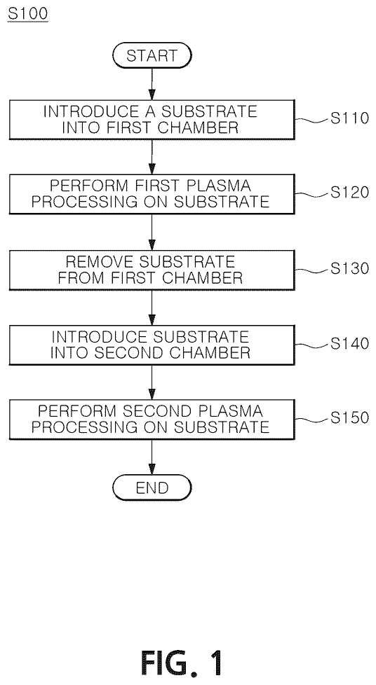

FIG. 1 is a flow chart of a method for processing a substrate according to an embodiment of the present disclosure.

Referring to FIG. 1, a method 100 for processing a substrate according to an embodiment of the present disclosure may include an operation of introducing a substrate into a first chamber (S110), an operation of performing first plasma processing on the substrate (S120), an operation of removing the substrate from the first chamber (S130), an operation of introducing the substrate into a second chamber (S140), and an operation of performing second plasma processing on the substrate (S150).

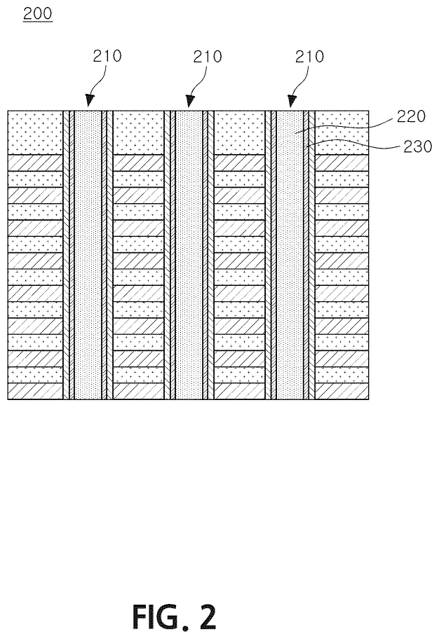

FIG. 2 illustrates a portion of a cross-section of a substrate 200 on which a method 100 for processing a substrate according to an embodiment of the present disclosure is performed. The substrate 200 may include one or more channel holes 210, a buried layer 220, and a polysilicon layer 230.

The one or more channel holes 210 may have a cylindrical shape concavely formed from a surface of the substrate 200 toward an interior of the substrate 200. The one or more channel holes 210 may be defined by an inner surface and a bottom surface formed in the substrate 200.

The buried layer 220 may be formed in the one or more channel holes 210 and may bury the one or more channel holes 210. The buried layer 220 may include an oxide formed by ALD.

The polysilicon layer 230 may be formed between the one or more channel holes 210 and the buried layer 220. The polysilicon layer 230 may be formed to cover an inner surface of the one or more channel holes 210.

According to the method 100 for processing a substrate, different processing may be performed on the substrate 200 in the operation of performing the first plasma processing (S120) and the operation of performing the second plasma processing (S150).

For example, in the operation of performing the first plasma processing (S120), processing for etching an upper portion of the buried layer 220 of the substrate 200 may be performed, and in the operation of performing the second plasma processing (S150), processing for an exposed surface of the polysilicon layer 230 of the substrate 200 may be performed.

The operation of performing the first plasma processing (S120) and the operation of performing the second plasma processing (S150) may be performed in different chambers. Accordingly, the substrate 200 may be removed from the first chamber after the operation of performing the first plasma processing (S120), and may be introduced into a second chamber different from the first chamber before the operation of performing the second plasma processing (S150).

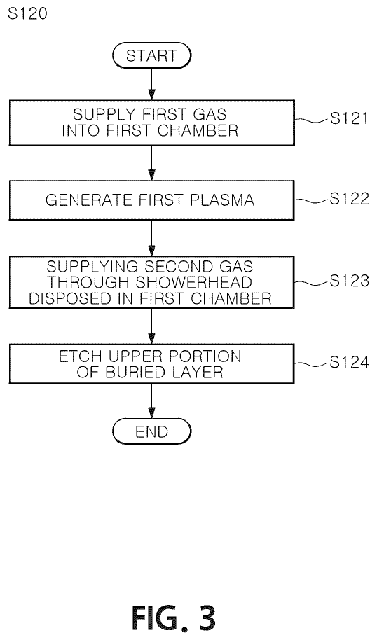

FIG. 3 is a flowchart of the operation of performing the first plasma processing (S120) included in the method 100 for processing a substrate. At least some of each operation included in the operation of performing the first plasma processing (S120) may be performed while the substrate is disposed in the first chamber.

Referring to FIG. 3, the operation of performing the first plasma processing (S120) may include an operation of supplying a first gas into the first chamber (S121), an operation of generating a first plasma (S122), an operation of supplying a second gas through a showerhead disposed in the first chamber (S123), and an operation of etching an upper portion of the buried layer (S124).

In the operation of supplying the first gas (S121), the first gas may include fluorine. The first gas may include at least one of, for example, NF₃, CF₄, C₄F8, and C₅F8.

In the operation of supplying the second gas (S123), the second gas may include hydrogen. The second gas may include, for example, at least one of NH₃, H₂, and HBr.

The operation of performing first plasma processing (S120) may further include an operation of supplying a third gas different from the first gas into the first chamber.

The third gas may be supplied simultaneously with the first gas. The third gas may include, for example, at least one of He, Ar, and N₂.

The operation of performing the first plasma processing (S120) may further include an operation of setting an internal temperature of the first chamber to a first temperature. The first temperature may have a temperature value in the range of, for example, 50 to 110° C. Additionally, the pressure of the first chamber in the operation of performing the first plasma processing (S120) may be set to have a value in the range of 200 mTorr to 8 Torr.

In the operation of etching an upper portion of the buried layer (S124), an upper portion of the buried layer 220 burying the one or more channel holes 210 of the substrate 200 may be etched. As the upper portion of the buried layer 220 is etched, at least a portion of the polysilicon layer 230 may be exposed.

A reaction mechanism of the operation of etching the upper portion of the buried layer (S124) may be performed according to, for example, the following chemical formulas 1 to 3.

NF₃(F*)+NH₃—NH₄F or HF Chemical Formula 1

NH₄F or HF+SiO₂→(NH₄)₂SiF₆(s)+H₂O Chemical Formula 2

(NH₄)₂SiF₆(s)→(Heat)→SiF₄(g)+NH₃(g)+HF(g) Chemical Formula 3

In the operation of etching the upper portion of the buried layer (S124), when the remaining fluorine reacts with an exposed polysilicon layer after the fluorine radical and NH₃ gas react, a surface of the polysilicon layer may be damaged.

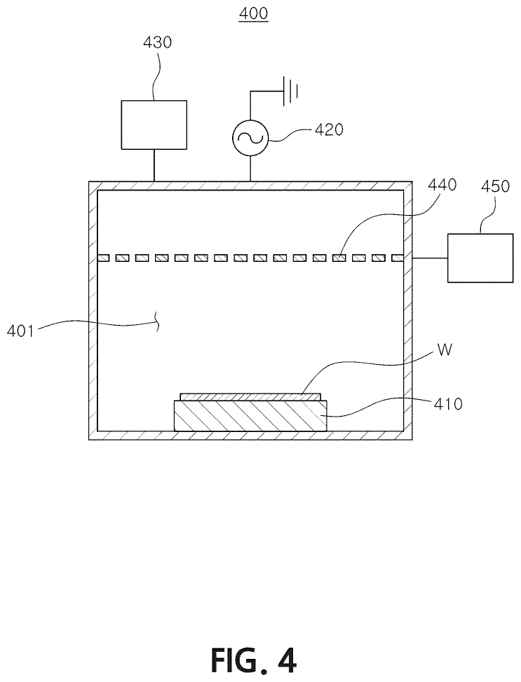

FIG. 4 schematically illustrates a first chamber on which some operations of the method 100 for processing a substrate are performed. As illustrated in FIG. 4, a first chamber 400 may include a first processing space 401 and a first support member 410 supporting a substrate W. The substrate W may have a structure identical to that of the substrate 200 illustrated in FIG. 2.

The first chamber 400 may have a plasma generation space and a first processing space 401 formed therein.

The plasma generation space may be a space to which gas for generating plasma is supplied and a temperature and pressure are controllable to generate plasma from the supplied gas.

The first processing space 401 may be an environment that may be controlled to an appropriate temperature and pressure to perform processing on the substrate W.

In the first processing space 401, the processing on the substrate W may be performed using the plasma. The processing on the substrate W may include, for example, an etching process.

The first support member 410 may include a substrate support surface supporting the substrate W and adsorbing and fixing the substrate W.

The first support member 410 may, for example, receive a DC voltage and adsorb the substrate W by electrostatic force. Additionally, the substrate support 410 may be controlled to have a preset temperature to control the processing of the substrate W.

The first chamber 400 may further include a first plasma generating unit 420, a first gas supply unit 430, a showerhead 440, and a second gas supply unit 450.

The first gas supply unit 430 may supply a first gas into the first chamber 400. The first gas may include fluorine. The first gas may include at least one of, for example, NF₃, CF₄, C₄F8, and C₅F8.

The first plasma generating unit 420 may generate a first plasma from the first gas in the first chamber 400. The first plasma generating unit 420 may generate a high-frequency voltage for generating plasma and may apply the high-frequency voltage to an electrode disposed in an upper portion of the first chamber 400.

When the first gas supply unit 430 supplies the first gas into the first chamber 400, and the high-frequency voltage is applied by the first plasma generating unit 420, the first plasma may be generated from the first gas in the first chamber 400. The high-frequency voltage may have, for example, a frequency in the range of 13 to 100 MHz and a power in the range of 50 to 1000 W.

The showerhead 440 may be disposed in an upper side of the first support unit 410 in an upper portion of the first chamber 400. The showerhead 440 may have a plurality of through-holes formed to penetrate through the showerhead 440 in a vertical direction.

The showerhead 440 may provide plasma radicals or one or more gases to the substrate W disposed downwardly through the plurality of through-holes.

The second gas supply unit 450 may supply a second gas into the first chamber 400 through the showerhead 440. The second gas may include hydrogen. The second gas may include, for example, at least one of NH₃, H₂, and HBr.

The first chamber 400 may further include a third gas supply unit supplying a third gas. The third gas supply unit may supply the third gas to the plasma generation space of the first chamber 400. The third gas may include, for example, at least one of He, Ar, and N₂.

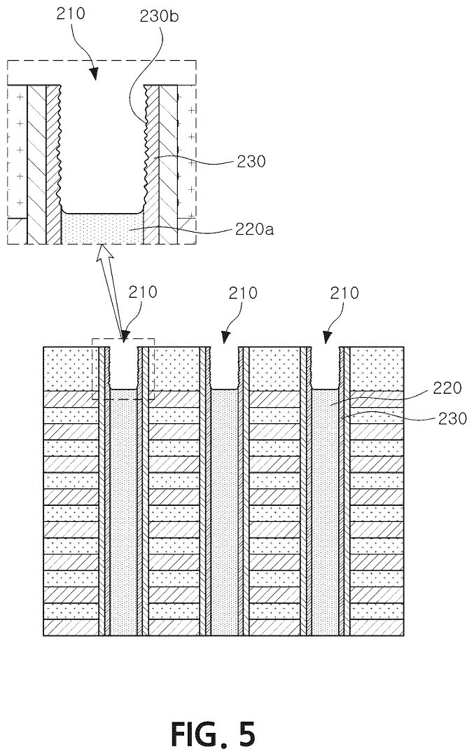

In the first chamber 400, the upper portion of the buried layer 220 may be etched using the first plasma and the second gas as illustrated in FIG. 5. When the upper portion of the buried layer 220 is etched, at least a portion of the polysilicon layer 230 may be exposed in an upper side of a remaining region 220a of the buried layer as much as the removed area of the buried layer.

In the process of etching the upper portion of the buried layer 220 using the first plasma and the second gas, an exposed surface of the polysilicon layer 230 may be damaged due to a reaction between fluorine and polysilicon. Accordingly, the roughness of an exposed surface 230a of the polysilicon layer 230 may increase.

When the roughness of the exposed surface 230a of the polysilicon layer increases, there may be a problem in which contact resistance of a semiconductor product increases and a lifespan of the product is shortened.

The present disclosure may reduce surface roughness of an exposed surface 230b of the polysilicon layer 230 that is damaged and has increased roughness in the process of etching the upper portion of a buried layer 220, through hydrogen plasma processing.

A system for processing a substrate in which the method 100 for processing a substrate according to an embodiment of the present disclosure is performed may include a substrate transfer unit transferring a substrate between chambers.

The substrate transfer unit may transfer a substrate after etching the upper portion of the buried layer and exposing at least a portion of the polysilicon layer in a first chamber, from the first chamber to the second chamber.

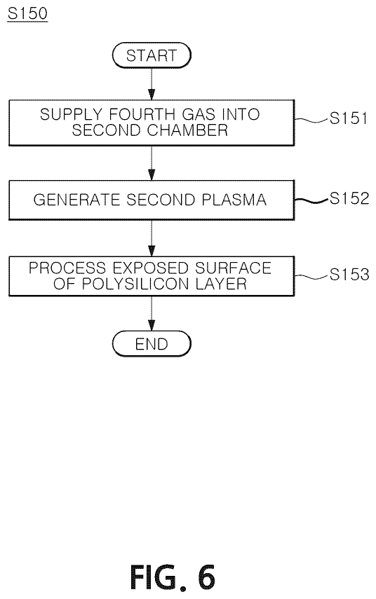

FIG. 6 is a flowchart of an operation of performing the second plasma processing (S150) included in the method 100 for processing a substrate. At least some of each operation included in the operation of performing the second plasma processing (S150) may be performed while the substrate is disposed in the second chamber.

Referring to FIG. 6, the operation of performing the second plasma processing (S150) may include an operation of supplying a fourth gas into the second chamber (S151), an operation of generating a second plasma (S152), and an operation of processing an exposed surface of the polysilicon layer (S153).

The operation of performing the second plasma processing (S150) may further include an operation of setting an internal temperature of the second chamber to a second temperature. The second temperature may have a temperature value in the range of, for example, 300 to 700° C. Additionally, the pressure of the second chamber in the operation of performing the second plasma processing (S150) may be set to have a value in the range of 0.5 to 4 Torr.

The second temperature set to the internal temperature of the second chamber in the operation of performing the second plasma processing (S150) may have a value higher than that of the first temperature set to the internal temperature of the first chamber in the operation of performing the first plasma processing (S120).

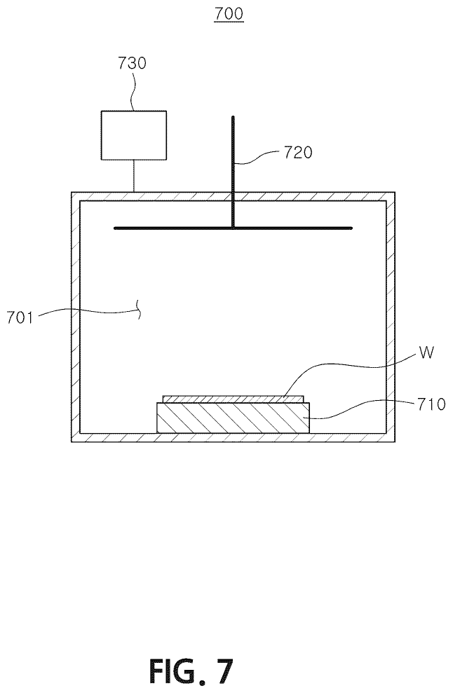

FIG. 7 schematically illustrates a second chamber in which some operations of the method 100 for processing a substrate are performed. As illustrated in FIG. 7, a second chamber 700 may include a second processing space 701 and a second support unit 710 supporting a substrate W. The substrate W is the substrate 200 illustrated in FIG. 2 that is introduced into the second chamber 700 after being subjected to the first plasma processing in the first chamber 400. The substrate W may have a shape as illustrated in FIG. 5.

The second chamber 700 may have a second processing space 701 formed therein. The second processing space 701 may be an environment that may be controlled to an appropriate temperature and pressure to perform processing on the substrate W.

In the second processing space 701, processing on the substrate W may be performed using plasma.

The second support unit 710 may include a substrate support surface supporting the substrate W and adsorbing and fixing the substrate W. The second support unit 710 may receive, for example, a direct current voltage and may adsorb the substrate W by electrostatic force. Additionally, the second support unit 710 may be controlled to have a preset temperature in order to control the processing of the substrate W.

The fourth chamber 700 may further include a second plasma generating unit 720 and a fourth gas supply unit 730.

The fourth gas supply unit 730 may supply a fourth gas into the second chamber 700. The fourth gas may include hydrogen. A flow rate of the fourth gas supplied into the second chamber 700 may be set to have a value in the range of, for example, 10 to 200 sccm.

The second plasma generating unit 720 may include an antenna generating a second plasma from the fourth gas in the second chamber 700. The high-frequency voltage applied by the second plasma generating unit 720 may have a frequency of, for example, 2 MHz to 2.5 GHZ and a power of 1000 to 3000 W.

In the second chamber 700, the exposed surface 230a of the polysilicon layer may be processed using a second plasma including hydrogen. The roughness of the exposed surface of the polysilicon layer may be reduced by the second plasma including hydrogen.

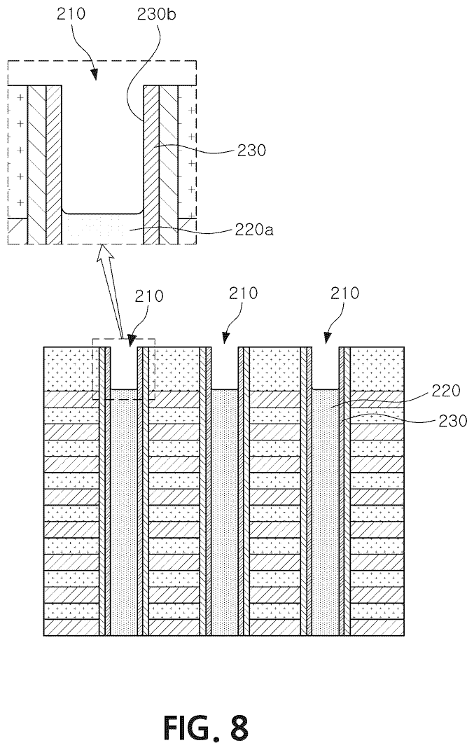

As compared to the exposed surface 230a of the polysilicon layer illustrated in FIG. 5, the roughness of the exposed surface 230b of the polysilicon layer of the substrate 200 after performing the second plasma processing may be reduced as illustrated in FIG. 8.

When a surface of a damaged polysilicon layer is exposed to hydrogen radicals in a high-temperature processing environment, silicon particles may move, thereby reducing the surface roughness of the polysilicon layer. The present disclosure may achieve an effect of surface curing of the exposed surface of the polysilicon layer by migrating the silicon particles through hydrogen plasma processing in the high-temperature environment.

Additionally, in describing the present disclosure, ‘˜ portion’ or ‘unit’ may be implemented in various manners, for example, by a processor, program instructions executed by the processor, a software module, a microcode, a computer program product, a logic circuit, an application-specific integrated circuit, firmware, or the like.

The contents of the method disclosed in the embodiment of the present application may be directly implemented by a hardware processor, or may be implemented and performed by a combination of hardware and software modules among the processors. The software module may be stored in a conventional storage medium such as a random-access memory, a flash memory, a read-only memory, a programmable read-only memory, an electrically erasable programmable memory, a register, or the like. The storage medium is disposed in the memory, and the processor reads the information stored in the memory and combines the information with the hardware to complete the contents of the above-described method. In order to avoid duplication, a detailed description is omitted here.

In the implementation process, each content of the above-described method may be completed by a logical integrated circuit of the hardware among the processors or an instruction in the form of software.

That is, those skilled in the art may recognize that each exemplary unit and algorithm operation described in the embodiments disclosed herein may be realized by combining electronic hardware or a combination of computer software and electronic hardware. Whether such a function is performed in a hardware manner or in a software manner is determined by the specific application and design constraints of the technical solution. Those skilled in the art may realize the described function using different methods for each specific application, but such realization should not be considered as being outside the scope of the present application.

It should be understood that in the several embodiments provided in the present application, the disclosed apparatus and method may be realized in other manners. For example, the apparatus embodiments described above are merely exemplary, for example, the division of the units is merely a kind of logical functional division, and other division methods may exist in actual implementation, and for example, a plurality of units or assemblies may be combined or integrated into another system, or some features may be ignored or not performed. On the other hand, the coupling or direct coupling or communication connection between each other displayed or discussed may be an indirect coupling or communication connection through some interface, apparatus or unit, and may be provided in an electrical, mechanical or other form.

The unit described as a separate component above may be physically separated, and the component displayed as a unit may or may not be a physical unit, that is, disposed in one point or distributed in a plurality of network units. Some or all of the units may be selected according to actual needs to realize the purpose of the solution of the present embodiment.

That is, each functional unit in each embodiment of the present application may be integrated into one processing unit, and each unit may exist alone, or two or more units may be integrated into one unit.

When the function is implemented in the form of a software functional unit and sold or used as an independent product, this may be stored in one computer-readable storage medium. Based on this understanding, a portion that essentially contributes to the prior art in technical solution of the present application, or a portion of the technical solution, may be implemented in the form of a software product, and the computer software product is stored in one storage medium, and includes a few instructions to cause one computer device (which may be a personal computer, a server, or a network device, or the like) to perform all or part of the operations of the method described in each embodiment of the present application. The storage medium described above includes various media capable of storing program codes, such as a USB memory, a mobile hard disk, a read-only memory (ROM), a random-access memory (RAM), a magnetic disk, a CD-ROM or the like.

The present disclosure is not limited to the embodiment described above and the accompanying drawings. The scope of rights of the present disclosure is intended to be limited by the appended claims. It will be understood by those skilled in the art that various substitutions, modification and changes in form and details may be made therein without departing from the spirit and scope of the present disclosure as defined by the appended claims.

What is claimed is:

1. A method for processing a substrate, comprising:
introducing a substrate into a first chamber;
performing first plasma processing on the substrate in the first chamber;
removing the substrate from the first chamber;
introducing the substrate into a second chamber; and
performing second plasma processing on the substrate in the second chamber,
wherein the substrate includes one or more channel holes and a buried layer formed in the one or more channel holes, and
different processing is performed on the substrate in the performing first plasma processing and the performing second plasma processing.

2. The method for processing a substrate according to claim 1, wherein the at least one channel hole includes an inner wall and a bottom surface formed concavely on a surface of the substrate,
the buried layer includes an oxide formed by ALD burying the at least one channel hole, and
the substrate further includes a polysilicon layer disposed between the at least one channel hole and the buried layer and formed to cover the inner wall of the at least one channel hole.

3. The method for processing a substrate according to claim 2, wherein the performing first plasma processing includes:
supplying a first gas including fluorine into the first chamber; and
generating a first plasma from the first gas in the first chamber.

4. The method for processing a substrate according to claim 3, wherein the performing first plasma processing includes:
supplying a second gas including hydrogen through a showerhead disposed in the first chamber; and
etching an upper portion of the buried layer using the first plasma and the second gas.

5. The method for processing a substrate according to claim 4, wherein the first gas includes at least one of NF₃, CF₄, C₄F8, and C₅F8, and
the second gas includes at least one of NH₃, H₂, and HBr.

6. The method for processing a substrate according to claim 4, wherein the performing first plasma processing includes:
supplying a third gas different from the first gas into the first chamber; and
wherein the third gas includes at least one of He, Ar, and N₂.

7. The method for processing a substrate according to claim 4, wherein in the etching an upper portion of the buried layer, at least a portion of the polysilicon layer is exposed.

8. The method for processing a substrate according to claim 7, wherein the performing second plasma processing includes:
supplying a fourth gas including hydrogen into the second chamber;
generating a second plasma from the fourth gas in the second chamber; and
processing an exposed surface of the polysilicon layer by the second plasma.

9. The method for processing a substrate according to claim 1, wherein the performing first plasma processing includes setting an internal temperature of the first chamber to a first temperature,
the performing second plasma processing includes setting an internal temperature of the second chamber to a second temperature, and
wherein the second temperature has a value higher than a value of the first temperature.

10. A system for processing a substrate, comprising:
a first chamber including a first processing space and a first plasma generation unit generating plasma in the first processing space therein;
a second chamber including a second processing space and a second plasma generating unit generating plasma in the second processing space; and
a substrate transfer unit transferring a substrate between the first chamber and the second chamber,
wherein the substrate includes one or more channel holes and a buried layer formed in the one or more channel holes, and
different processing is performed on the substrate in the first chamber and the second chamber.

11. The system for processing a substrate according to claim 10, wherein the buried layer includes an oxide formed by ALD, and
the substrate further includes a polysilicon layer formed between the one or more channel holes and the buried layer.

12. The system for processing a substrate according to claim 11, wherein the first chamber further includes a first gas supply unit supplying a first gas including fluorine, and
the first plasma generating unit generates a first plasma from the first gas in the first chamber.

13. The system for processing a substrate according to claim 12, wherein the first chamber further includes a showerhead disposed in the first chamber and a second gas supply unit supplying a second gas including hydrogen through the showerhead, and
an upper portion of the buried layer is etched using the first plasma and the second gas in the first chamber.

14. The system for processing a substrate according to claim 13, wherein the first gas supply unit supplies the first gas including at least one of NF₃, CF₄, C₄F8, and C₅F8, and
the second gas supply unit supplies the second gas including at least one of NH₃, H₂, and HBr.

15. The system for processing a substrate according to claim 13, wherein the first chamber further includes a third gas supply unit supplying a third gas different from the first gas,
wherein the third gas supply unit supplies the third gas including at least one of He, Ar, and N₂.

16. The system for processing a substrate according to claim 13, wherein the substrate transfer unit transfers the substrate after the upper portion of the buried layer is etched and at least a portion of the polysilicon layer is exposed in the first chamber, from the first chamber to the second chamber.

17. The system for processing a substrate according to claim 16, wherein the second chamber further includes a fourth gas supply unit supplying a fourth gas including hydrogen,
the second plasma generation unit generates a second plasma from the fourth gas, and
an exposed surface of the polysilicon layer is processed by the second plasma in the second chamber.

18. The system for processing a substrate according to claim 10, wherein an internal temperature of the first chamber is set to a first temperature, and
an internal temperature of the second chamber is set to a second temperature,
wherein the second temperature has a value higher than a value of the first temperature.

19. A method for processing a substrate, comprising:
introducing a substrate into a first chamber;
generating a first plasma from a first gas including fluorine in the first chamber;
performing first plasma processing on the substrate in the first chamber;
removing the substrate from the first chamber;
introducing the substrate into a second chamber;
generating a second plasma from a second gas including hydrogen in the second chamber;
performing second plasma processing on the substrate in the second chamber,
wherein the substrate includes one or more channel holes, a buried layer burying the one or more channel holes in the one or more channel holes, and a polysilicon layer disposed between the one or more channel holes and the buried layer and formed to cover an inner wall of the one or more channel holes,
the performing first plasma processing includes etching an upper portion of the buried layer using the first plasma, and
the performing second plasma processing includes processing an exposed surface of the polysilicon layer.

20. The method for processing a substrate according to claim 19, wherein the performing a first plasma includes setting an internal temperature of the first chamber to a first temperature, and
the performing a second plasma includes setting an internal temperature of the second chamber to a second temperature,
wherein the second temperature has a value higher than a value of the first temperature.
